(19) United States
(12) Patent Application Publication
(10) Pub. No.: US 2011/0017263 A1
(43) Pub. Date: Jan. 27, 2011

(54) METHOD AND DEVICE FOR FABRICATING A SOLAR CELL USING AN INTERFACE PATTERN FOR A PACKAGED DESIGN

(75) Inventors: KEVIN R. GIBSON, Redwood City, CA (US); NEELSEN CO, Pleasanton, CA (US); ZHI-MIN LING, Cupertino, CA (US); CHRIS MIHAI, Morgan Hill, CA (US); ALELIE FUNCELL, Fremont, CA (US); RAMON ROSAL REGLOS, San Ramon, CA (US)

Correspondence Address: AMPACC Law Group, PLLC, 6100 219th Street SW, Suite 580, Mountlake Terrace, WA, 98043, US

(73) Assignee: Solaria Corporation, Fremont, CA (US)

(21) Appl. No.: 12/205,574

(22) Filed: Sep. 5, 2008

Related U.S. Application Data
(60) Provisional application No. 60/970,241, filed on Sep. 5, 2007.

(51) Int. Cl. H01L 31/042; H01L 31/18

(52) U.S. Cl. 136/246; 438/68; 257/E31.127

(57) ABSTRACT

A method and device of fabricating a photovoltaic strip. The method includes providing a photovoltaic cell having a front surface and a back surface and forming a first grid pattern on the front surface and second grid pattern on the back surface. The first grid pattern includes a first plurality of strip columns in parallel in a first direction and a plurality of grid lines in parallel in a second direction perpendicularly crossing the first plurality of strip columns. The second grid pattern includes a plurality of blocks separated by a plurality of streets parallel in the second direction and a second plurality of strip columns parallel in the first direction. The method further includes dicing the photovoltaic cell along the plurality of streets into a plurality of photovoltaic strips. Each of the plurality of photovoltaic strips includes at least one of the plurality of grid lines.

### CROSS-REFERENCES TO RELATED APPLICATIONS

This application claims priority of U.S. patent application Ser. No. 60/970,241, entitled “METHOD AND DEVICE FOR FABRICATING A SOLAR CELL USING AN INTERFACE PATTERN FOR A PACKAGED DESIGN,” filed on Sep. 5, 2007 commonly assigned, and is incorporated by reference in its entirety.

### STATEMENT AS TO RIGHTS TO INVENTIONS MADE UNDER FEDERALLY SPONSORED RESEARCH OR DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention relates generally to solar energy techniques. In particular, the present invention provides a method and resulting device fabricated from a plurality of concentrating elements respectively coupled to a plurality of photovoltaic regions. More particularly, the present method and device for fabricating a solar cell using a predetermined grid pattern for packaged design. In a specific embodiment, the grid pattern is implemented to provide metallization connection for the solar cell. Merely by way of example, the invention has been applied to solar panels, commonly termed modules, but it would be recognized that the invention has a much broader range of applicability.

As the population of the world increases, industrial expansion has lead to an equally large consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed.

Concurrent with oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many characteristics that are very desirable! Solar energy is renewable, clean, abundant, and often widespread. Certain technologies developed often capture solar energy, concentrate it, store it, and convert it into other useful forms of energy.

Solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of silicon bearing wafer materials. Such wafer materials are often costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification, and may be described in more detail below.

From the above, it is seen that techniques for improving solar devices is highly desirable. Particularly, for packaged design fabrication of the photovoltaic cell, panel, or assembly coupled with light concentration module, there are needs for an interface pattern with desired physical, electrical, and optical coupling properties.

### BRIEF SUMMARY OF THE INVENTION

The present invention relates generally to solar energy techniques. In particular, the present invention provides a method and resulting device fabricated from a plurality of concentrating elements respectively coupled to a plurality of photovoltaic regions. More particularly, the present method and device for fabricating a solar cell using a predetermined grid pattern for packaged design. In a specific embodiment, the grid pattern is implemented to provide metallization connection for the solar cell. Merely by way of example, the invention has been applied to solar panels, commonly termed modules, but it would be recognized that the invention has a much broader range of applicability.

In a specific embodiment, the invention provides a structure for fabricating a photovoltaic strip. The structure includes a first grid pattern associated with a front surface of a photovoltaic cell. The photovoltaic cell is characterized by a first dimension in a first direction and a second dimension in a second direction which is perpendicular to the first direction. The first grid pattern includes a first plurality of strip columns in parallel with the first direction and a plurality of grid lines in parallel with the second direction crossing the first plurality of strip columns. Each of the first plurality of strip columns has a first width and a first length equal to the first dimension. The plurality of grid lines is equally spaced to cumulatively cover substantially the first length. Each of the plurality of grid lines has a second width and a second length substantially equal to the second dimension. The second width is substantially smaller than the second length. Additionally, the structure includes a second grid pattern associated with a back surface of the photovoltaic cell. The second grid pattern includes a plurality of blocks separated by a plurality of streets in parallel with the second direction and by a second plurality of strip columns in parallel with the first direction. Each of the plurality of blocks has a third width provided between two neighboring streets. Each of the plurality of streets has a fourth width provided between two neighboring blocks. Each of the second plurality of strip columns has a fifth width and a length equal to the first dimension. The fourth width is smaller than the third width. The structure further includes a alignment characteristic that each grid line of the first grid pattern corresponds to a single row of blocks of the second grid pattern in the second direction. Moreover, the structure includes a misalignment characteristic that the first plurality of strip columns of the first grid pattern shifts away from any one of the second plurality of strip columns of the second grid pattern.

In another specific embodiment, the invention provides a structure for fabricating a photovoltaic strip. The structure includes a first grid pattern associated with a front surface of a photovoltaic cell. The first grid pattern includes a first plurality of strip columns in parallel with a first direction and a plurality of grid lines in parallel with a second direction crossing the first plurality of strip columns. The second direction is perpendicular to the first direction. Each of the plurality of grid lines is equally spaced by a first distance. Additionally, the structure includes a second grid pattern associated with a back surface of the photovoltaic cell. The second grid pattern includes a plurality of blocks separated by a plurality of streets in parallel in the second direction and by a second plurality of strip columns in parallel in the first direction. Each of the plurality of blocks has a width provided between two neighboring streets. The width is substantially equal to the first distance. Moreover, the structure includes a alignment characteristic that each grid line of the first grid pattern corresponds to a single row of blocks of the second grid pattern in the second direction. Furthermore, the structure includes a misalignment characteristic that the first plurality of strip columns of the first grid pattern shifts away from any one of the second plurality of strip columns of the second grid pattern.

In yet another specific embodiment, the invention includes a method of fabricating a photovoltaic strip for solar concentrator module. The method includes providing a photovoltaic cell having a front surface and a back surface. The photovoltaic cell is characterized by a first dimension in a first direction and a second dimension in a second direction which is perpendicular to the first direction. The method further includes forming a first grid pattern on the front surface. The firs grid pattern includes a first plurality of strip columns in parallel in the first direction with a first length being equal to the first dimension. The first grid pattern further includes a plurality of grid lines in parallel in the second direction crossing the first plurality of strip columns. The plurality of grid lines is equally spaced and cumulatively covering substantially the first dimension and each has a first width and a second length extending to substantially the second dimension. Additionally, the method includes forming a second grid pattern on the back surface. The second grid pattern includes a plurality of blocks separated by a plurality of streets parallel in the second direction and a second plurality of strip columns parallel in the first direction. Each of the plurality of blocks having a second width provided between two neighboring streets. A row of blocks in the second direction is aligned with one corresponding grid line of the first grid pattern. Moreover, the method includes dicing the photovoltaic cell along the plurality of streets into a plurality of photovoltaic strips. Each of the plurality of photovoltaic strips includes at least one of the plurality of grid lines and having a width substantially equal to the second width and a length of the second dimension.

In yet still another specific embodiment, the invention also provides a method of fabricating a photovoltaic strip for solar concentrator module. The method includes providing a photovoltaic cell having a front surface and a back surface, which can be characterized by a first dimension in a first direction and a second dimension in a second direction perpendicular to the first direction. Additionally, the method includes applying a first screen on the front surface. The first screen includes a first plurality of strip openings in parallel with the first direction and a plurality of line openings in parallel with the second direction crossing the first plurality of strip openings. Each of the first plurality of strip openings has a first width and a first length equal to the first dimension and the plurality of line openings is equally spaced to cumulatively cover substantially the first length. Each of the plurality of line openings has a second width and a second length substantially equal to the second dimension and the second width is substantially smaller than the second length. The method further includes applying a second screen on the back surface. The second screen includes a plurality of block openings separated by a plurality of street fills in parallel with the second direction and by a second plurality of strip openings in parallel with the first direction. Each of the plurality of block openings has a third width provided between two neighboring street fills and each of the plurality of street fills has a fourth width provided between two neighboring block openings. Each of the second plurality of strip openings has a fifth width and a length equal to the first dimension and the fourth width is smaller than the third width. In one embodiment, a single row of block openings of the second screen in the second direction is aligned with corresponding one of the plurality of line openings of the first screen. In another embodiment, the first plurality of strip openings of the first screen shifts away from any one of the second plurality of strip openings of the second screen. Moreover, the method includes printing a first metallic paste on the front surface through the first screen to form a first grid pattern. The first grid pattern includes a plurality of grid lines along the second direction with a length substantially equal to the second dimension. The method further includes printing a second metallic paste on the back surface through the second screen to form a second grid pattern. The second grid pattern includes a plurality of street sections along the second direction and free of the second metallic paste. The method further includes firing both the first surface and the second surface to cure the first grid pattern and the second grid pattern respectively. Furthermore, the method includes dicing the photovoltaic cell along the plurality of street sections into a plurality of photovoltaic strips. Each of the plurality of photovoltaic strips includes at least one of the plurality of grid lines and has a width substantially equal to the third width and a length of the second dimension.

In a specific embodiment, the present method and system include a grid pattern having certain physical dimensions for the photovoltaic cells with desirable with spatial tolerances. As an example, the tolerances relate to thickness, width, and length of each detached photovoltaic region.

In another specific embodiment, the present method and system include a grid pattern having desirable electrical characteristics for the photovoltaic cells. As an example, the electrical characteristics relate to spatial features and layout of the interconnections and base properties of the metallic materials used to form the grid pattern. These properties include resistivity, solderability, and interface material compatibility as well.

In yet another specific embodiment, the grid pattern based on present method is provided within a vicinity of an interface region to achieve desirable optical coupling properties between the photovoltaic region and concentrating element in the packaged design for super-photovoltaic cells or photovoltaic panels. As an example, the coupling properties include but not limited to index of refraction, base material type, surface characteristic, and adhesion properties to the front cover of the photovoltaic cell or panel.

Many benefits are achieved by way of the present invention over conventional techniques. For example, the present technique provides an easy to use process that relies on conventional technology such as silicon materials in the photovoltaic strips, although other materials also can be used. Additionally, the method provides a process that is compatible with conventional process technology without substantial modifications to conventional equipment and processes. Preferably, the invention provides for an improved grid pattern with grid line density for increased current density and one finger-like conductive grid line on the front surface of solar concentrator module per concentrating element, which has less blocking or shadowing effect and high module efficiency. Such grid pattern includes saw streets on the back surface of the photovoltaic cell. These saw streets are areas without metallic paste which allows for the saw to cut quickly without binding up or dragging metal across the cut surface and allows for the greater saw life which in turn reduces sawing costs. It also helps reduce chip outs which help keep the efficiency up. The size of the saw street can be minimized to maintain cell efficiency. But at the same time the saw street must be wide enough to allow for the saw cut and margin for any misalignment. In a preferred embodiment, these improved grid patterns can be applied to both 125 mm and 156 mm mono and multi crystalline PV cells. Many of these benefits are also available for laser cutting. The diced photovoltaic strips will be used to package a solar module with concentrating elements where the photovoltaic material per surface area is about 50% or less than conventional solar panel module. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagram illustrating a cross-sectional view of a photovoltaic region of a typical unpackaged solar cell;

FIG. 2 is a simplified diagram illustrating an expanded view of a solar concentrator module according to an embodiment of the present invention;

FIG. 3 is a simplified diagram of a front side grid pattern according to an embodiment of the present invention;

FIG. 4 is a simplified diagram of a back side grid pattern corresponding to the front side grid pattern shown in FIG. 3 according to an embodiment of the present invention;

FIG. 5 is a simplified diagram outlining a method of using pre-determined grid patterns to fabricate a plurality of photovoltaic strips for solar concentrator module according to an embodiment of the present invention;

FIG. 6 is a simplified diagram illustrating a cross-sectional view of an interface pattern between a typical photovoltaic region and a front cover member of a partially packaged photovoltaic cell according to an embodiment of the present invention; and

FIG. 7 is a simplified diagram illustrating various grid patterns to fabricate a plurality of photovoltaic strips according to embodiments of the present invention.

### DETAILED DESCRIPTION OF THE INVENTION

The present invention relates generally to solar energy techniques. In particular, the present invention provides a method and resulting device fabricated from a plurality of concentrating elements respectively coupled to a plurality of photovoltaic regions. More particularly, the present method and device for fabricating a solar cell using a predetermined grid pattern for packaged design. In a specific embodiment, the grid pattern is implemented to provide metallization connection for the solar cell. Merely by way of example, the invention has been applied to solar panels, commonly termed modules, but it would be recognized that the invention has a much broader range of applicability.

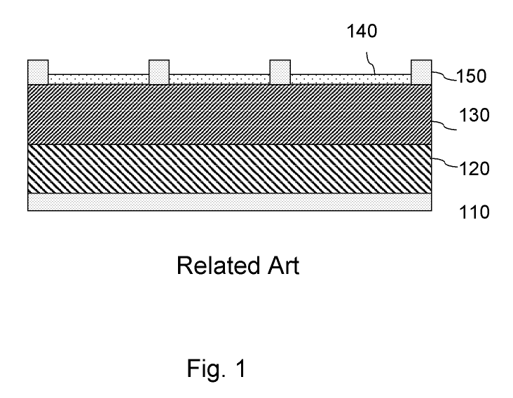

The most common types of solar cells are based on the photovoltaic effect, which occurs when light falling on a two-layer semiconductor material, usually one layer with excess free electron holes or vacancies and another one with excess free electrons forming a p-n junction, produces a potential difference, or voltage, between the two layers. FIG. 1 is a simplified diagram illustrating a cross-sectional view of an unpackaged solar cell including a photovoltaic region made by a p-n junction which includes a p-type semiconductor layer 120 and a n-type semiconductor layer 130, an antireflective coating 140, a conductive layer 110 and a front contact grid 150. As shown the conductive layer 110 typically is a metal film covering the entire back surface of the PV cell and acts as a bottom electrode. At the same time, a front contact grid 150, also made of metallic material, serves as a top electrode for collecting electrons for the PV cell. As shown in FIG. 1, the front contact grid 150 penetrates the antireflective coating 140 and makes direct contact with the n-type semiconductor layer 130. In one embodiment, there may be an additional native oxide layer between the layer 130 and antireflective coating 140. The front contact grid 150 should also penetrate that oxide layer.

In another embodiment, though not explicitly shown in FIG. 1, the front contact grid 150 has a predetermined pattern. As the solar cell is fabricated from a raw wafer, the pre-determined grid pattern is to match with the specific geometry of desired PV cell structure. Particularly, where the contact grid is positioned and how it is laid out depend on the specific solar cell package design and affect the eventual energy conversion efficiency per unit surface area with minimized usage of photovoltaic materials. Certain embodiments of the present invention provide a grid pattern that may be used for fabricating a plurality of photovoltaic strips in conjunction with a front cover member with a plurality of light concentrating elements for a packaged solar concentrator cell or module. Of course, there can be other variations, modifications, and alternatives.

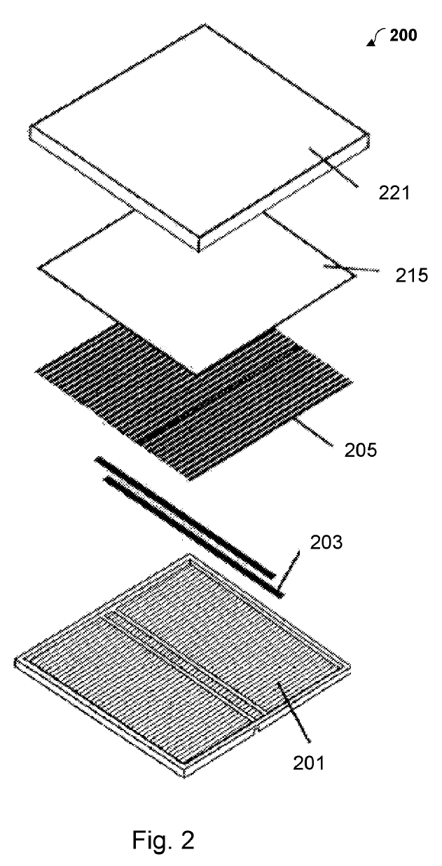

FIG. 2 is a simplified diagram of a solar concentrator cell according to an embodiment of the present invention. This diagram is merely an example, which should not unduly limit the scope of the claims herein. One of ordinary skill in the art would recognize other variations, modifications, and alternatives. As shown is an expanded view of device structure of the solar concentrator cell 200, which includes various elements. The device 200 has a back cover member 201, which includes an inner surface area and a back area. The back cover member also has a plurality of sites, which are spatially disposed, for electrical members, such as bus bars, and a plurality of photovoltaic regions. Alternatively, the back cover can be free from any patterns and is merely provided for support and packaging. Of course, there can be other variations, modifications, and alternatives.

In a preferred embodiment, the device 200 has a plurality of photovoltaic strips 205, each of which is disposed overlying the inner surface area of the back cover member. In a preferred embodiment, the plurality of photovoltaic strips correspond to a cumulative area occupying a total photovoltaic spatial region, which is active and converts sunlight into electrical energy.

Further, the device 200 includes an encapsulating material 215 overlying a portion of the back cover member 201. That is, an encapsulating material forms overlying the plurality of strips, and exposed regions of the back cover, and electrical members. In a preferred embodiment, the encapsulating material can be a single layer, multiple layers, or portions of layers, depending upon the application. In alternative embodiments, as noted, the encapsulating material can be provided overlying a portion of the photovoltaic strips or a surface region of the front cover member, which would be coupled to the plurality of photovoltaic strips. Of course, there can be other variations, modifications, and alternatives.

In a specific embodiment, the device 200 includes a front cover member 221 coupled to the encapsulating material 215. That is, the front cover member 221 is formed overlying the encapsulate to form a multilayered structure including at least the back cover, bus bars, plurality of photovoltaic strips, encapsulate, and front cover. In a preferred embodiment, the front cover includes one or more concentrating elements, which concentrate (e.g., intensify per unit area) sunlight onto the plurality of photovoltaic strips. That is, each of the concentrating elements can be associated respectively with each of or at least one of the photovoltaic strips.

Upon assembly of the back cover, bus bars, photovoltaic strips, encapsulate, and front cover, an interface region is provided along at least a peripheral region of the back cover member and the front cover member. The interface region may also be provided surrounding each of the strips or certain groups of the strips depending upon the embodiment. The device has a sealed region and is formed on at least the interface region to form an individual solar cell from the back cover member and the front cover member. The sealed region maintains the active regions, including photovoltaic strips, in a controlled environment free from external effects, such as weather, mechanical handling, environmental conditions, and other influences that may degrade the quality of the solar cell. Additionally, the sealed region and/or sealed member (e.g., two substrates) protect certain optical characteristics associated with the solar cell and also protects and maintains any of the electrical conductive members, such as bus bars, interconnects, and the like. Of course, there can be other benefits achieved using the sealed member structure according to other embodiments.

In a specific embodiment, the present invention provides a packaged solar concentrator module being capable of generating electrical power with stand-alone operation or by combining with other solar cell assemblies. The packaged solar concentrator module includes rigid front cover member having a front cover surface area and a plurality of concentrating elements thereof. Depending upon applications, the rigid front cover member consist of a variety of materials. For example, the rigid front cover is made of polymer material. As another example, the rigid front cover is made of transparent polymer material having a reflective index of about 1.4 or 1.42 or greater. According to an example, the rigid front cover has a Young's Modulus of a suitable range. Each of the concentrating elements has a length extending from a first portion of the front cover surface area to a second portion of the front cover surface area. Each of the concentrating elements has a width provided between the first portion and the second portion. Each of the concentrating elements having a first edge region coupled to a first side of the width and a second edge region provided on a second side of the width. The first edge region and the second edge region extend from the first portion of the front cover surface area to a second portion of the front cover surface area. The plurality of concentrating elements is configured in a parallel manner extending from the first portion to the second portion.

In a preferred embodiment, for solar modules with light concentrators the total photovoltaic spatial region occupies a smaller spatial region than the surface area of the back cover. That is, the total photovoltaic spatial region uses less silicon or other PV material than conventional solar cells for a given solar cell size. In a preferred embodiment, the total photovoltaic spatial region occupies about 80% and less of the surface area of the back cover for the individual PV cell. Depending upon the embodiment, the photovoltaic spatial region may also occupy about 70% and less or 60% and less or preferably 50% and less of the surface area of the back cover or given area of a PV cell. Of course, there can be other percentages that have not been expressly recited according to other embodiments. Here, the terms “back cover member” and “front cover member” are provided for illustrative purposes, and not intended to limit the scope of the claims to a particular configuration relative to a spatial orientation according to a specific embodiment. Further details of each of the various elements in the solar cell can be found throughout the present specification and more particularly below.

In another preferred embodiment, the photovoltaic spatial region is characterized an elongated rectangular shape, for example, a width of about 2 mm and a length of about 125 mm. Each of these photovoltaic strips can be positioned to align with the concentrating elements of the front cover member such that the front surface of the photovoltaic strips faces the exit region of the concentrating element and the back surface of the photovoltaic strip overlying the photovoltaic region on the inner surface of the back cover member. Of course, there can be other variations, modifications, and alternatives. For example, the embodiment may further includes a first electrode member that is coupled to a first region of each of the plurality of photovoltaic strips and a second electrode member coupled to a second region of each of the plurality of photovoltaic strips. In one embodiment, the first electrode member and the second electrode member are formed using a pre-determined grid pattern for the front surface of the photovoltaic strips. In another embodiment, the metallic grid pattern is formed on a PV cell and then the PV cell is cut into the strips following the pattern.

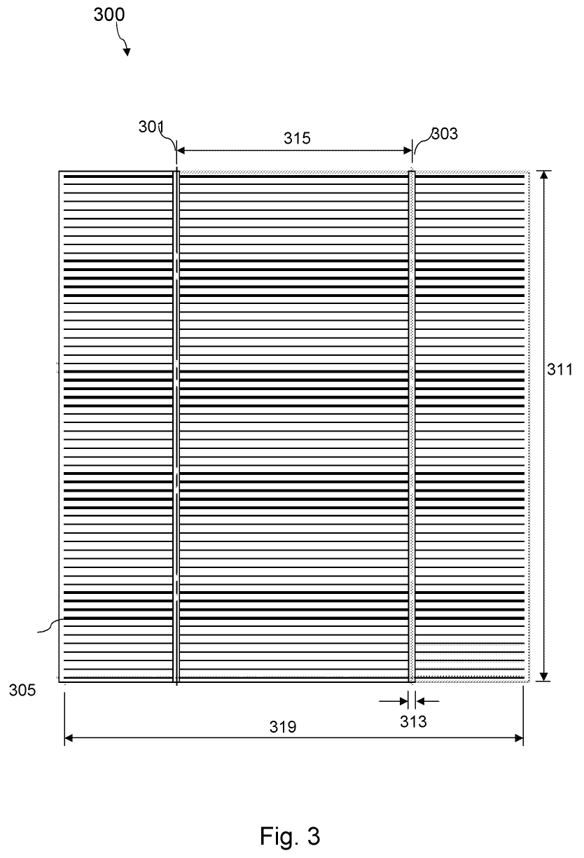

FIG. 3 is a simplified diagram of a front side grid pattern according to an embodiment of the present invention. This diagram is merely an example, which should not unduly limit the scope of the claims herein. One of ordinary skill in the art would recognize other variations, modifications, and alternatives. As shown is a pre-determined grid pattern 300 which are laid out on a rectangular shaped plane. In one embodiment, the grid pattern 300 includes a first strip column 301 and a second strip column 303. The first strip column 301 and the second strip column 303 each has a length and a width 313, and is in parallel to each other in the length direction. The length of the two strip columns are the same as the length 311 of the rectangular shaped plane. For example, the length 311 is 125 mm for mono-crystalline silicon PV cells used in the solar module according to certain embodiments of the present invention. Accordingly, the width 313 of the strip column can be about 1.8 mm. The center separation between the first strip column 301 and the second strip column 303 is denoted by 315. The relative position of each strip column may be placed symmetrically within the rectangular shaped plane. In another embodiment, the grid pattern 300 includes a plurality of finger-like grid lines 305 extended in parallel across nearly the whole length 311. In yet another embodiment, the finger-like grid lines are equally spaced. For example, the spacing between two neighboring grid lines is about 2.08 mm. Each grid line 305 is perpendicular to both strip columns 301 and 303 and has a length 319 extended nearly across the whole width of the rectangular shaped plane. In one embodiment, the finger-like grid lines 305 extending out of different strip columns (301 and 303) coincide with each other as shown in FIG. 3. Each of the plurality of grid lines 305 has a second width 317. The second width is much thinner than the first width 313. For example, the second width 317 is about 0.25 mm. Of course, there can be other variations, modifications, and alternatives.

Once the grid pattern is determined, it can be used to make a screen for thick film metallization process. For example, the screen is made of a mesh stainless steel with about 10 to 14 microns emulsion build up. In one embodiment, a photovoltaic (PV) cell with a built-in p-n junction formed by a n-type semiconductor layer overlying a p-type semiconductor layer is provided, followed by the application of such a screen with the pre-determined grid pattern. For example, the screen with grid pattern 300 is used. Then a first metallic paste can be directly printed through the screen on the front side of the PV cell. For example, the first metallic paste comprises a mixed fine powers of silver, aluminum, dielectrics, glass, organic components and other additives for promoting bonding and sintering, etc.

In one embodiment, the screen printing is done on the n-type semiconductor layer of the photovoltaic cell. In another embodiment, the grid pattern 300 is formed on an anti-reflection coating overlying the n-type semiconductor layer of the photovoltaic cell. The printed first metallic paste is capable of penetrating through the anti-reflective coating and a native oxide layer to form good conductive contact with the n-type semiconductor layer. Finally, after the screen is removed and other processes such as drying and firing are performed, a layer of the first metallic paste with the grid pattern 300 including a plurality of metallic grid lines 305 and two strip columns (301 and 303) are formed. The plurality of grid lines 305 are formed equally spaced in parallel manner, each having a width 317 and a length 319 on the front side of PV cell. Additionally, the two metallic strip columns each having a width 313 and a length 311 extending across all the plurality of grid lines are formed perpendicular to those grid lines. In one embodiment, after the PV cell is diced into a plurality of PV strips with a certain width, each PV strip shall include at least one grid line along its length. In a specific embodiment, the finger is aligned with the central line of each PV strip. Moreover, after the cutting, the two strip columns become two specific spots for each PV strip. When packaging the plurality of the PV strips into the solar concentrator module, these corresponding spots will be aligned and be utilized for soldering the PV strip with two front side metal bus bars respectively to form a complete top electrode the solar module. Of course, there can be other variations, modifications, and alternatives.

In a specific embodiment, the grid pattern 300 can be applied to 125 mm square shaped mono-crystalline silicon PV cells. In another specific embodiment, the grid pattern 300 described above can be applied to 156 mm square shaped multi-crystalline silicon PV cells. Of course, there can be other variations, modifications, and alternatives. For example, the PV cells can also be made of amorphous silicon, copper indium diselenide (CIS), Copper Indium Gallium Selenide (CIGS), Cadmium Telluride (CdTe), thin film materials, or nanostructured materials.

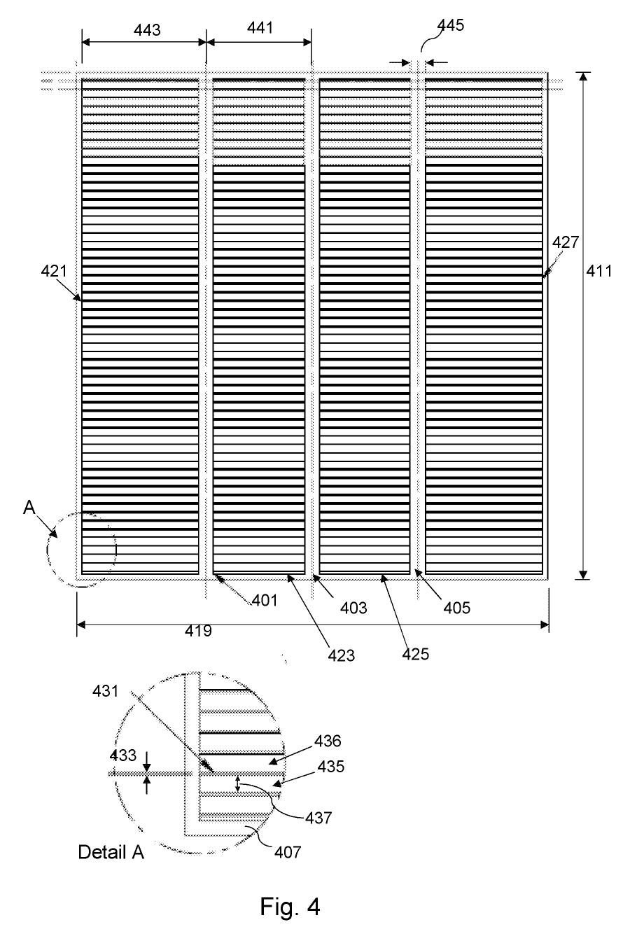

Correspondingly, for each front side grid pattern there need a matched back side grid pattern for the same PV cell. FIG. 4 is a simplified diagram of a back side grid pattern corresponding to the front side grid pattern shown in FIG. 3 according to an embodiment of the present invention. This diagram is merely an example, which should not unduly limit the scope of the claims herein. One of ordinary skill in the art would recognize other variations, modifications, and alternatives. As shown in FIG. 4 is a pre-determined grid pattern 400 which is laid out on a rectangular shaped plane that has a substantially identical dimension as the grid plane shown in FIG. 3.

In one embodiment, the grid pattern 400 includes three elongated strip columns 401, 403, and 405 along the length 411 of the grid plane. The length 411 is substantially equal to the length 311 of the grid plane shown in FIG. 3. For example, the length 411 or the length 311 is equal to about 125 mm. In another example, the length 411 or the length 311 is equal to about 156 mm. Each elongated strip column has a same width 445. For example, the width 445 is about 4 mm. One strip column 403 is positioned with its own central line aligned with a central line of the grid plane. Two other strip columns 401 and 405 are in parallel to the strip column 403 and are located symmetrically on each side of the grid plane central line with a separation 441. The separation 411 is a centered distance between two elongated strip columns, for example, 401 and 403. In another embodiment, the grid pattern 400 includes only two strip columns (401 and 405, with 403 being removed), symmetrically being positioned on the grid plane relative to its central line. In a specific embodiment, relative position of the elongated strip columns (401, 403, and/or 405) of the grid pattern 400 is intentionally located at different positions relative to the strip columns (301 and 303) of the grid pattern 300. Of course, there can be other variations, modifications, and alternatives.

Referring to the FIG. 4, the three strip columns divide the rectangular shaped grid plane into four sections, 421, 423, 425, and 427, respectively. In one embodiment, the grid pattern 400 includes a plurality of blocks/streets combination structures occupied each of the four sections except a peripheral region 407 of the grid plane. Each of the plurality of blocks/streets is a rectangular shape with its length perpendicular to the strip columns 401, 403, or 405. For example, as shown in a detail view of a corner “A” of the grid pattern 400, part of section 421 is illustrated. As shown a block 435 has a width 437 and a same length as the length 443 of the section 421. Each of the other blocks within the section 421 has the same width and the same length. Between two neighboring blocks there is a street. For example, street 431 is between block 435 and block 436. Street 431 has a width 433 as shown in FIG. 4. Similarly, any block in section 423 has a width 437 and a length 441. For example, the width 437 is about 2 mm. Due to the symmetric positions of the strip columns 401, 403, and 405 relative to the central line of the grid plane, the blocks within section 425 should have substantially same dimensions as the blocks in section 423, the blocks within the section 427 should have substantially same dimensions as the blocks in section 421. The same configuration description above also applies to the streets between blocks in corresponding sections. Of course, there can be other variations, modifications, and alternatives.

In a specific embodiment, the grid pattern 400 can be applied to 125 mm square shaped mono-crystalline silicon PV cells. In another specific embodiment, the grid pattern 400 described above can be applied to 156 mm square shaped multi-crystalline silicon PV cells. Of course, there can be other variations, modifications, and alternatives. For example, the PV cells can be made in a form or semiconductor wafers or in the form of films or foils. In another example, the PV cells can also be made of amorphous silicon, copper indium diselenide (CIS), Copper Indium Gallium Selenide (CIGS), Cadmium Telluride (CdTe), thin film materials, or nanostructured materials.

Similarly, screen printing technique can be used to print a second metallic paste on the back side of a same PV cell that has a first metallic paste printed on its front side. For example, the screen printed second metallic paste forms the grid pattern 400 on the back side of a PV cell and the screen printed first metallic paste forms the grid pattern 300 on the front side of the same PV cell. Unlike the grid pattern 300 which comprises a plurality of grid lines formed by the first metallic paste, the grid pattern 400 comprises a plurality of blocks made of the second metallic paste while leaving a plurality of streets (such as 431) free of the second metallic paste. Additionally, the strip columns (401, 403, and 405) also cover the second metallic paste. In certain embodiment, the strip columns are over-printed with a third metallic paste which is designed with better solderability than the second metallic paste for the strip columns will be coupled with bus bars during module packaging. Of course, there can be other variations, modifications, and alternatives.

In one embodiment, the second metallic paste and the first metallic paste have different composition. The front side, for the solar cell, is responsible for absorbing sun light and generating most of electrical carriers. The first metallic paste serves a role as a conductor for efficiently contacting the n-type semiconductor layer and transporting the photo-generated current without adversely affecting the semiconductor properties and without damaging the p-n junction. Typically, the first metallic paste requires to carry but not limit to the following properties of penetration of native oxide layer and anti-reflective coating, high conductivity, good line resolution, and good solderability. For example, the first metallic paste comprises mainly silver based fine powders. The function of the back side conductor served by the second metallic paste is to act as the second electrode in the solar cell. Typically, the second metallic paste requires to have a good ohmic contact, a function of back-surface field, and a good solderability or weldability. For example, the second metallic paste comprises silver mixed with a small amount of aluminum. Of course, there can be other variations, modifications, and alternatives. For example, a third metallic paste, which is silver based, may be over-printed along the strip columns perpendicular to the blocks/streets after the second metallic paste is printed.

In a preferred embodiment, the grid pattern 300 printed on the front side of a PV cell and the grid pattern 400 printed on the back side of the same PV cell is relatively aligned based on a predetermined design. For example, the strip columns 301 and 303 on the front side are in parallel with the strip columns 401, 403 and 405 on the back side. Additionally, each grid line 305 of the grid pattern 300 on the front side is aligned its length with four corresponding blocks in four consecutive sections of the grid pattern 400. In one embodiment, after the PV cell is diced into a plurality of PV strips with a certain width, each PV strip shall include at least one grid line along its length on its front side. In a specific embodiment, the grid line is aligned with the central line along the length of each PV strip. Of course, there can be other variations, modifications, and alternatives. For example, some design moves the finger to the one edge or both length edges of the PV strip.

In another preferred embodiment, the plurality of streets associated with the back side grid pattern 400 an be utilized for dicing the cell along with. For example, a dicing saw is applied to cut the cell along each street so that a plurality of PV strips can be obtained. As mentioned earlier, the grid pattern 400 formed by the screen printing metallic paste comprises the plurality of streets lack of the metallic materials. Therefore, cutting along the streets can be done quickly without binding or dragging metal across the cut surface allowing for greater saw life and in turn reducing cost. In another embodiment, the street width 433 is minimized to ensure efficient usage of the PV cell while is wide enough to avoid misalignment during the dicing. For example, the street width is about 0.25 mm. In another example, if a laser beam is utilized for cutting the PV cell, the same configuration of the streets on the back side grid pattern should also help to facilitate the cutting with minimum energy cost and PV material loss.

In yet another preferred embodiment, because of the alignment between the front side grid pattern and the back side grid pattern, the dicing the PV cell into a plurality of PV strips along the plurality of streets on the back side creates a correspondence relationship between the grid lines 305 of the grid pattern 300 and the plurality of PV strips. In one specific embodiment, one grid line along its length is correspondingly located substantially close to a central line direction of each of the plurality of PV strips. Each of these PV strips obtained has a width substantially similar to the width 437 of the blocks and a length substantially equal to the width of the grid plane. For example, the length of PV strips equals to the width 419 of grid pattern 400 and the PV strip width is about 2.0 mm. In another embodiment, each of these PV strips can be cumulatively attached with a plurality of exit regions of a concentrator structure. For example, each of these PV strips is the photovoltaic strip 205 that is packaged into the solar cell device 200 which has a top cover member comprising a plurality of concentrating elements each having an elongated exit region. As another example, the PV strips can be packaged into a solar concentrator module that has an 1 meter by 1.6 meter top cover member. The large top cover member includes a glass or plastic webbing and a plurality of concentrating elements integrally formed on the back side of the webbing. The PV strips are attached cumulatively to occupy a whole length, of about 1 meter and longer, of each exit region of the plurality of concentrating elements. Of course, there can be other variations, modifications, and alternatives.

In a specific embodiment, the concentrating element associated with the solar cell device 200 or other solar concentrator module may have a truncated pyramid shape elongated along its length while the cross-section is a trapezoid shape. The top of the trapezoid is an aperture region for collecting light rays from the sun, and the two side regions are configured to redirect light rays via total internal reflection to the bottom called an exit region which has a width equal to about a half of or smaller than that of the aperture. Light rays collected by the aperture region either directly reach the exit region or are re-directed to the exit region by reflection at the two side regions, providing a geometric concentration effect. While in this configuration, there will be a natural local minimum of the light intensity along the central line of the exit region based on the geometric optics. Therefore, according to an embodiment of the present invention the grid pattern design allows the printed conductive grid line being located along the central line of the PV strip so that the thin metallic grid line imposes a relative small loss of light conversion efficiency for the solar cell or solar concentrator module. Of course, there can be other variations, modifications, and alternatives. For example, the grid pattern may be changed or different alignment is implemented so that two conductive grid lines are formed along the edge regions of each PV strips after dicing from the PV cell. Thus, after coupling the PV strip with the exit region of the concentrating element the conductive grid lines may be totally outside the exit regions so that the effect of light blocking due to the front side grid line is minimized.

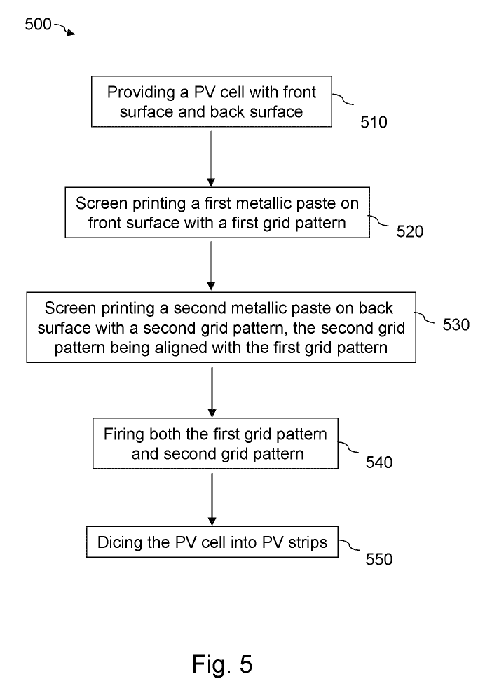

In an alternative embodiment, the present invention provides a method of fabricating a solar cell with a plurality of PV strips using the grid patterns with certain alignment. FIG. 5 is a simplified diagram illustrating a method 500 for making the grid patterns on front side and back side of a PV cell according to an embodiment of the present invention. This diagram is merely an example, which should not unduly limit the scope of the claims herein. One of ordinary skill in the art would recognize other variations, modifications, and alternatives. As shown method 500 preferably is outlined by the following processes:
1. Process 510: Providing a PV cell with a front surface and a back surface in a pre-determined shape;
2. Process 520: Forming a first conductive layer with a first grid pattern on the front surface;
3. Process 530: Forming a second conductive layer with a second grid pattern on back surface, the second grid pattern being aligned with the first grid pattern.
4. Process 540: Firing both the first grid pattern and second grid pattern;
5. Process 550: Dicing the PV cell into a plurality of PV strips.

These sequences of processes provide a way of performing a method according to an embodiment of the present invention. As can be seen, the method provides a technique for fabricating a photovoltaic strip for solar concentrator cell or module according to an embodiment of the invention. Of course, there can be variations, modifications, and alternatives. Some processes can be performed in different order. For example, process 530 may be performed before process 520. Some processes can be removed or added. For example, the PV cell provided in Process 510 might have a patterned metallization film on its back surface on regions corresponding to a plurality of blocks particularly along one spatial direction. Then process 530 may be omitted or process 520 may need extra alignment steps for forming the first grid pattern to exiting patterned metallization film on the back surface. In another example, the process 530 may comprise over-printing a different metallic paste on several strip columns that are located perpendicular to the spatial direction of the plurality of blocks. Further details of the present method and resulting structures can be found throughout the present specification and more particularly below.

In process 510, a PV cell is provided, which has a front surface, a back surface, and a predetermined shape. In one embodiment, the predetermined shape is a rectangular shape with a width of a first dimension and a length of a second dimension, or a substantially square shape for certain manufacturing convenience. As described in some earlier paragraphs, the PV cell front surface typically is used for receiving the sun light for converting into electric current when it is packaged into the solar cell or module. Therefore, the front surface may include some overlayers including anti-reflective coating and native oxides on top of an n-type semiconductor layer. The front surface requires to be added a top electrode for collecting the charges generated by photons from the sun light rays. Similarly, the back surface of the PV cell may be a p-type semiconductor layer overlaid with a native oxide. A bottom electrode for solar cell is needed to be formed at the back surface. Of course, there can be other variations, modifications, and alternatives.

In process 520 a first conductive layer is formed on the front surface of the PV cell. In one embodiment, the first conductive layer is served to be a top electrode for solar concentration cells or modules and can be formed through thick-film metallization. The thick-film metallization has been employed in a variety of industries to generate patterned, highly conductive conductors on ceramic, glass, and plastic substrates. In a specific embodiment, one of thick-film metallization method utilized for forming the top electrode is screen printing a selected metallic paste with a first grid pattern on the front surface of the PV cell. Of course, there can be other variations, modifications, and alternatives. For example, the first grid pattern is the grid pattern 300 as shown in FIG. 3, including a plurality of parallel grid lines and two strip columns in perpendicular direction extending across the PV cell.

In a preferred embodiment, the forming the first conductive layer comprises one or more processes including preparing a mesh screen with a predetermined pattern, preparing a metallic paste, and printing the metallic paste on the front surface where the mesh screen which is pre-applied on. The mesh screen can be a mesh stainless steel with 10 to 14 μm emulsion build up. For example, a 200 or 325-mesh stainless steel screen is used. The metallic paste usually is in a polymeric form containing fine powers or flakes of metal, glass, organic components or additives etc with certain desired viscosity and resistivity. As the electrode for front surface of PV cells which is responsible for absorbing light and generating most of the electrical carriers, the metallic paste needs to form good contact with the n-type semiconductor layer and efficiently transport the photo-generated current without adversely affecting the semiconductor properties and without damaging the p-n junction. For example, silver thick film is preferred to be the front surface electrode conductor on mono and polycrystalline wafers. In one example, the silver-based paste has a viscosity of about 200-280 Pa s and a resistivity of about 3 to 4.5 μΩcm for the photovoltaic applications. In another example, the composition of metallic paste may be affected by the nature and composition of the anti-reflective coating applied on the front surface. For example, for TiOₓ—SiOₓ anti-reflective coating, silver based metallic paste is used. As an example, one of commercially available Solamet™ polymer thick film silvers provided by DuPont (DuPont Microcircuit Materials, Research Triangle Park, NC, 27709) is used for making the top electrode of PV cells for solar concentrator modules. Of course, there can be other variations, modifications, and alternatives.

Similarly in process 530 of method 500 according to an embodiment of the present invention, a second conductive layer with a second grid pattern is formed on back surface. The second grid pattern is required to be relatively aligned with the first grid pattern on the front surface. The process 530 includes the same technique as set forth in the process 520 by screen printing another metallic paste. For conventional PV cell, the second conductive layer serves the second electrode on the back surface, which usually is not illuminated, and is not subjected to constraints on electrode geometry. For fabricating PV strips out of the PV cell for packaging into the solar concentrator module, the second grid pattern is necessitated for facilitating the dicing of the PV strips with a desired alignment. In one specific embodiment, the second grid pattern is the grid pattern 400 including a plurality of streets in parallel separating a plurality of blocks as shown in FIG. 4. Additionally, the plurality of streets in the second grid pattern is aligned to be in parallel with the grid lines of the first grid pattern. Each grid line of the first grid pattern is associated with a pair or neighboring streets of the second grid pattern. Of course, there can be other variations, modifications, and alternatives.

In a specific embodiment, the screen printing process 520 and 530 provide a wet print of the metallic paste of 18 to 30 μm in thickness on both the front surface and the back surface. The paste is then dried for about 10 or more minutes in a circulated-air static oven. Alternatively, an infrared light based drier may be employed for inline processing at the temperature range of about 125 to 200° C. for 10 or less minutes. Moreover, the process 540 is employed to fire the printed grid patterns using an infrared source in a well-ventilated furnace. The firing profile depends on specific cell configuration and thickness. Typically, peak temperatures up to 980° C. with time above 600° C. being between 2 seconds and 30 seconds are employed. The resulted grid lines have a reduced thickness of 10 μm or less. Of course, there can be other variations, modifications, and alternatives. For example, process 530 can be performed first followed by process 540 on the back surface of the PV cell. Then process 520 is performed followed by process 540 on the front surface of the PV cell.

In another embodiment, the metallic paste screen printed on the back surface can be either the same or different as one used for front surface in terms of chemical composition. As an example, for processing with silicon-based PV cell, Aluminum is added to the metallic paste for the back surface with intention for forming an Al—Si alloy which functions as a back-surface field, enhancing the efficiency of the PV cell by contributing the photocurrent and cell voltage. The added aluminum also helps the paste, which has lower viscosity of about 60 to 90 Pa s, to penetrate the native oxide layer on the PV cell and generate better contact with silicon. In a specific example, the metallic paste for back surface is a mixture of silver and aluminum with about 2.5% aluminum composition. Also, the firing process 540 for the back surface may include using higher peak temperature and different cycle time for maximizing the back-surface effect, then followed by the front surface screen printing and a separate firing process for front surface at a lower temperature. In one embodiment, if pure Al paste is used for back surface, the process 540 may be a co-firing process at a temperature of 700 to 780° C.

In another embodiment, the second grid pattern includes several strip columns that are extended across the PV cell along a direction perpendicular to the plurality of streets. These strip columns can be over-printed with a silver-base paste after the plurality of blocks being printed with Al/Ag paste. These strip columns with silver-based paste may be co-fired with other patterned paste or fired separately and are intended for soldering with conduction bus bars when packaging into the modules. The silver-base paste provides superior solderability or weldability so that the efficiency of the module is enhanced. Of course, there can be other variations, modifications, and alternatives.

Referring to FIG. 5, the process 550 is performed to cut the PV cell into a plurality of PV strips after the grid patterns are formed and aligned. In a specific embodiment, the plurality of streets of the second grid pattern on the back surface is characterized by substantially free of any metallic paste, along which the PV strips will be cut by a dicing saw. The lack of metallic materials make the cutting quicker without dragging the metallic paste in the cutting surface and also improves the life time of the dicing saw, which effectively reduces manufacture cost. The plurality of streets have an optimized width that is minimized for best PV material utilization and cell efficiency and is sufficiently wide for cutting without misalignment. In another specific embodiment, for a same PV cell the first grid pattern is the grid pattern 300 shown in FIG. 3 and the second grid pattern is the grid pattern 400 shown in FIG. 4. The grid pattern 400 is used to align with the grid pattern 300 in such a way that one grid line on the front surface is located relatively at the central line of a PV strip after it is cut along two neighboring streets on the back surface. One grid line for the front surface is intended for minimizing the light blocking and shadowing effect. While the grid line has sufficient width for handling increasing current density in module level. In other words, the top electrode for the PV strip is mainly a central grid line along the length of the PV strip. The bottom electrode of the PV strip is mainly the film covering the whole block(s). Both the top electrode and the bottom electrode of the PV strip also include two or more contact spots in the middle area of the PV strip (originated from two or more strip columns before cutting) made of silver-based paste. In one embodiment, the contact spots on the front surface are relatively shifted away from the contact spots on the back surface. These contact spots are used for soldering with the solar module conduction wires or bus bars. Of course, there can be other variations, modifications, and alternatives.

The method 500 described above is merely an example for fabricating photovoltaic strip using certain grid patterns. Depending on the applications and structures of the solar concentrator cell or module, the PV strip to be attached with the concentrating elements may have different geometry and dimension which in turns may need different grid patterns. Different metallic paste compositions and paste firing process conditions may be applied when a variety of PV materials are used. For example, the PV cell can be made of single crystalline silicon, polycrystalline silicon, amorphous silicon, copper indium diselenide (CIS), Copper Indium Gallium Selenide (CIGS), Cadmium Telluride (CdTe), thin film materials, or nanostructured materials. Correspondingly, the metallic paste may comprise polymeric form of sliver, aluminum, gold, platinum, palladium, as well as glass powders and other organic components. While the low cost, high conductivity, process simplicity, and solid-state chemistry for desired solderability, bonding, cleansing, adhesion, and circuit integrity, etc should be included as the criterion for paste selection. Of course, there can be other variations, modifications, and alternatives.

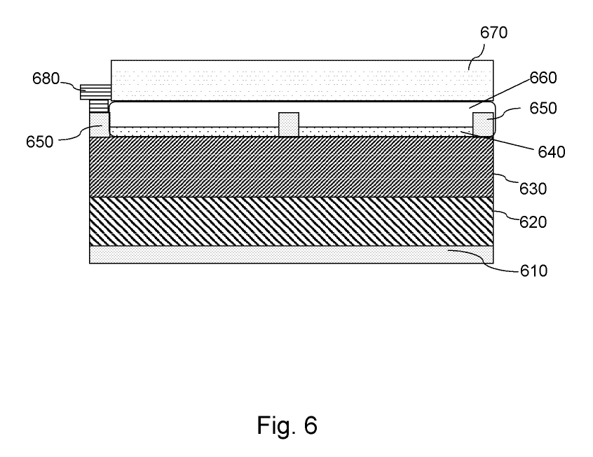

FIG. 6 is a simplified diagram illustrating a cross-sectional view of an interface pattern between a typical photovoltaic region and a front cover member of a partially packaged photovoltaic cell according to an embodiment of the present invention. This diagram is merely an example, which should not unduly limit the scope of the claims herein. One of ordinary skill in the art would recognize other variations, modifications, and alternatives. As shown, a photovoltaic region made by a p-n junction includes a p-type semiconductor layer 620 and a n-type semiconductor layer 630, an antireflective coating 640, a conductive layer 610 and a front contact grid 650. In one embodiment, the conductive layer 610 is the second metallic paste film formed on the back surface of the PV cell using the method 500 and acts as a bottom electrode. In another embodiment, the front contact grid 650 is the first metallic paste material formed on the front surface of the PV cell, serves as a top electrode for collecting electrons generated by the PV cell.

As shown in FIG. 6, an coupling material 660 is applied over the front contact grid 650, which is then directly bonded with a front cover member 670 of a module. In an specific embodiment, the front cover member 670 is a light concentrating element that is capable of collecting 50% -80% more light energy into the photovoltaic light receiving region represented by the area not covered by the grid pattern 650. For example, the light concentrating element is a glass or acrylic material with index of refraction about 1.4 to 1.5. Of course, there are other alternatives, variations, and modifications.

In a specific embodiment, depending on the package design at a certain location of the grid pattern 650, an external conductor 680 is coupled to the metallic grid so that the photo-electric current can be collected from one cell to another for extracting energy that originated from the sun light. For example, the external conductor is a bus bar across all cell assembly or whole solar module. In another example, the external conductor 680 is coupled with the grid pattern 650 by soldering.

In another specific embodiment, a grid pattern formed according to the present method and system, such as the grid pattern 650, includes certain physical characteristics that have a desirable physical dimensions with desirable with spatial tolerances for a packaged photovoltaic cells. For example, the tolerances relate to thickness, width, and length of each detached photovoltaic region. In another example, the length and width of the grid pattern formed according certain embodiments of present method and system each respectively has a tolerance of ±0.5 mm or less. This tolerance should apply to each and every type of cell size provided in the market, including but not limiting 103 mm, 125 mm, 156 mm, or 200 mm, or 300 mm in dimension. In yet another example, the thickness of the metallic film within the printed pattern is desired to have a tolerance of about a few microns.

In another specific embodiment, the present method and system includes a grid pattern, such as the grid pattern 650 and 610 formed using method 500, having desirable interface electrical characteristics for the packaged photovoltaic cells. For example, the electrical characteristics relate to spatial features and layout of the interconnections and base properties of the metallic paste materials used to form the grid pattern as shown in FIG. 6. These properties include resistivity, solderability, and interface material compatibility as well. In another example, the grid pattern 610 includes silver-aluminum paste material has a desired electric resistivity of about 5 to 7 and the grid pattern 650 on the front may include silver paste material with a resistivity of about 2 to 10 μΩ/cm (the resistivity unit corresponds to mΩ/sq at 10 μm paste thickness). As another example, the solderability direct relates to coupling the metallic paste material in the grid pattern 650 with the external connectors 680 such as bus bars in packaged design. Typical solder for this application includes tin/lead/silver alloy solder that can be applied at moderate temperature about 200 to 250° C. Of course, there are many other alternatives, variations, and modifications.

In yet another specific embodiment, the grid pattern 650, particularly the front side grid pattern, is provided within a vicinity of an interface region to achieve desirable optical coupling properties between the photovoltaic region and concentrating element in the packaged design for super-photovoltaic cells or photovoltaic panels. For example, the coupling properties include, but not limited to, index of refraction, base material type, surface characteristic, and adhesion properties to the front cover of the photovoltaic cell or panel. The metallic paste material 650 may include certain additives for enhancing its bonding with the optical coupling material applied in the interface region. The optical coupling material also includes, but not limit to, aliphatic polyurethane, which can be processed to be index matched with both the photovoltaic cell below and the concentrating element above. As an example, the concentrating element made of glass or acrylic material usually has an index of refraction of 1.4 to 1.5. The photovoltaic strip has an index of refraction of about 3. In addition, the types of metallic paste and optical coupling material and the interface roughness may affect the adhesion property during packaging and reliability for on-field operation with a packaged cell or panel over the entire range of environmental constraints set by industry standards.

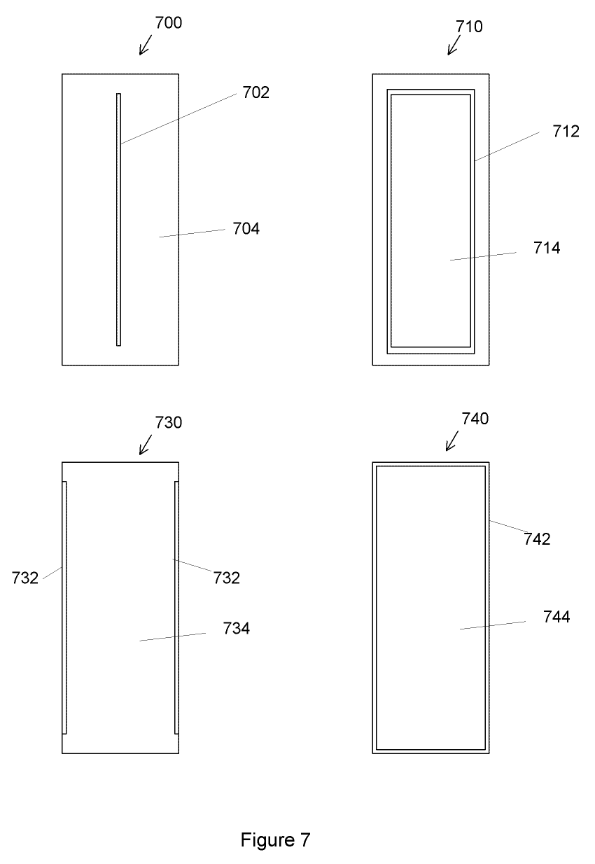

Depending on the embodiment, there still can be other variations. For example, the finger like grid line may have other configurations as exemplified in the simplified diagrams in FIG. 7. As shown in FIG. 7, a first grid pattern design 700 has a grid line 702 aligned with central line along the length of each PV strip 704, which is commonly used in conventional PV assembly.

Referring to FIG. 7, a second grid pattern 710 according to an embodiment of the present invention is provided. As shown, the second grid pattern has a first loop finger configuration where a grid line 712 is disposed in a peripheral region of a PV strip 714.

In an alternative embodiment, a third grid pattern 730 is provided. The third grid pattern has two edge fingers per PV strip. Grid lines 732 are disposed along each of the edges along the length of a photovoltaic strip 734 and not connected in this configuration.

Yet alternatively, a fourth grid pattern 740 is illustrated in FIG. 7. The fourth grid pattern has a second loop finger configuration where a grid line 742 covers an entire edge region of a photovoltaic strip 744.

Many advantages may be achieved by the second grid pattern, the third grid pattern, and the fourth grid pattern. Each of these grid patterns can provide improved device yield and improved device performance. For example, in the case of PV strip breakage, the grid pattern would still provide a way to collect the electrical charges from the PV cell generated by the photons. The third grid pattern and the fourth grid pattern provide additional benefits of reduced charge recombination at the edges and overall device performance.

It is also understood that the examples and embodiments described herein are for illustrative purposes only and that various modifications or changes in light thereof will be suggested to persons skilled in the art and are to be included within the spirit and purview of this application and scope of the appended claims.

1. A structure for fabricating a photovoltaic strip, the structure comprising:
a first grid pattern associated with a front surface of a photovoltaic cell, the photovoltaic cell being characterized by a first dimension in a first direction and a second dimension in a second direction, the second direction being perpendicular to the first direction, the first grid pattern including a first plurality of strip columns in parallel with the first direction and a plurality of grid lines in parallel with the second direction crossing the first plurality of strip columns, each of the first plurality of strip columns having a first width and a first length equal to the first dimension, the plurality of grid lines being equally spaced to cumulatively cover substantially the first length, each of the plurality of grid lines having a second width and a second length substantially equal to the second dimension, the second width being substantially smaller than the second length;
a second grid pattern associated with a back surface of the photovoltaic cell, the second grid pattern including a plurality of blocks separated by a plurality of streets in parallel with the second direction and by a second plurality of strip columns in parallel with the first direction, each of the plurality of blocks having a third width provided between two neighboring streets, each of the plurality of streets having a fourth width provided between two neighboring blocks, each of the second plurality of strip columns having a fifth width and a length equal to the first dimension, the fourth width being smaller than the third width;
a alignment characteristic that each grid line of the first grid pattern corresponds to a single row of blocks of the second grid pattern in the second direction; and
a misalignment characteristic that the first plurality of strip columns of the first grid pattern shifts away from any one of the second plurality of strip columns of the second grid pattern.

2. The structure of claim 1 wherein the photovoltaic cell can be made of at least one material selected from single crystal silicon, polycrystalline silicon, amorphous silicon, copper indium diselenide (CIS), Copper Indium Gallium Selenide (CIGS), Cadmium Telluride (CdTe), thin film materials, or nanostructured materials.

3. (canceled)

4. (canceled)

5. (canceled)

6. (canceled)

7. (canceled)

8. The structure of claim 1 wherein the first grid pattern is a patterned conductive layer on the front surface.

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. The structure of claim 1 wherein the first length is about 125 mm for mono-crystalline silicon PV cell and about 0.156 mm for polycrystalline silicon PV cell.

21. (canceled)

22. (canceled)

23. The structure of claim 1 wherein the plurality of grid lines being equally spaced to cumulatively cover substantially the first length includes one grid line with about 1.05 mm distance away from one edge of the PV cell and another grid line with about 1.05 mm distance away from an opposite edge of the PV cell.

24. The structure of claim 1 wherein the first plurality of strip columns includes at least a first strip column and a second strip column, the first strip column being positioned symmetrically with the second strip column relative to the central line of the PV cell in the first direction and being separated from each other by a centered distance of about 62.5 mm.

25. The structure of claim 1 wherein the second grid pattern is a patterned conductive layer on the back surface.

26. (canceled)

27. (canceled)

28. (canceled)

29. (canceled)

30. (canceled)

31. (canceled)

32. (canceled)

33. (canceled)

34. (canceled)

35. A structure for fabricating a photovoltaic strip, the structure comprising:
a first grid pattern associated with a front surface of a photovoltaic cell, the first grid pattern including a first plurality of strip columns in parallel with a first direction and a plurality of grid lines in parallel with a second direction crossing the first plurality of strip columns, the second direction being perpendicular to the first direction, each of the plurality of grid lines being equally spaced by a first distance;
a second grid pattern associated with a back surface of the photovoltaic cell, the second grid pattern including a plurality of blocks separated by a plurality of streets in parallel in the second direction and by a second plurality of strip columns in parallel in the first direction, each of the plurality of blocks having a width provided between two neighboring streets, the width being substantially equal to the first distance;
a alignment characteristic that each grid line of the first grid pattern corresponds to a single row of blocks of the second grid pattern in the second direction; and
a misalignment characteristic that the first plurality of strip columns of the first grid pattern shifts away from any one of the second plurality of strip columns of the second grid pattern.

36. (canceled)

37. (canceled)

38. (canceled)

39. (canceled)

40. (canceled)

41. (canceled)

42. The structure of claim 35 wherein the first grid pattern is a patterned conductive layer on the front surface.

43. The structure of claim 42 wherein the pattern conductive layer is within a vicinity of an interface region where the front surface of the PV cell is adhesively bonded with one or more concentrating elements by one or more optical coupling materials.

44. (canceled)

45. The structure of claim 42 wherein the patterned conductive layer on the front surface is a first metallic paste forming the first plurality of strip columns and a plurality of grid lines.

46. (canceled)

47. (canceled)

48. (canceled)

49. The structure of claim 35 wherein each of the plurality of grid lines has a width of about 100 to 150 μm.

50. The structure of claim 35 wherein each of the first plurality of strip columns has a width of about 1.8 mm and a length of the photovoltaic cell in the first direction.

51. (canceled)

52. (canceled)

53. (canceled)

54. The structure of claim 35
wherein the second grid pattern is a patterned conductive layer on the back surface; and
wherein the patterned conductive layer on the back surface is a second metallic paste forming the plurality of blocks separated by the plurality of street and a third metallic paste forming the second plurality of strip columns.

55. (canceled)

56. (canceled)

57. (canceled)

58. (canceled)

59. (canceled)

60. (canceled)

61. (canceled)

62. (canceled)

63. A method of fabricating a photovoltaic strip for solar concentrator module, the method comprising:
providing a photovoltaic cell having a front surface and a back surface, the photovoltaic cell being characterized by a first dimension in a first direction and a second dimension in a second direction, the second direction being perpendicular to the first direction;
applying a first screen on the front surface, the first screen comprising:
a first plurality of strip openings in parallel with the first direction;
a plurality of line openings in parallel with the second direction crossing the first plurality of strip openings, each of the first plurality of strip openings having a first width and a first length equal to the first dimension, the plurality of line openings being equally spaced to cumulatively cover substantially the first length, each of the plurality of line openings having a second width and a second length substantially equal to the second dimension, the second width being substantially smaller than the second length;
applying a second screen on the back surface, the second screen comprising:
a plurality of block openings separated by a plurality of street fills in parallel with the second direction and by a second plurality of strip openings in parallel with the first direction, each of the plurality of block openings having a third width provided between two neighboring street fills, each of the plurality of street fills having a fourth width provided between two neighboring block openings, each of the second plurality of strip openings having a fifth width and a length equal to the first dimension, the fourth width being smaller than the third width;
wherein,
a single row of block openings of the second screen in the second direction is aligned with corresponding one of the plurality of line openings of the first screen;
the first plurality of strip openings of the first screen shifts away from any one of the second plurality of strip openings of the second screen;
printing a first metallic paste on the front surface through the first screen to form a first grid pattern, the first grid pattern comprising a plurality of grid lines along the second direction with a length substantially equal to the second dimension;
printing a second metallic paste on the back surface through the second screen to form a second grid pattern, the second grid pattern comprising a plurality of street sections along the second direction and free of the second metallic paste;
firing both the first surface and the second surface to cure the first grid pattern and the second grid pattern respectively; and
dicing the photovoltaic cell along the plurality of street sections into a plurality of photovoltaic strips, each of the plurality of photovoltaic strips including at least one of the plurality of grid lines and having a width substantially equal to the third width and a length of the second dimension.

64. The method of claim 63 wherein the photovoltaic cell can be made of at least one material selected from single crystal silicon, polycrystalline silicon, amorphous silicon, copper indium diselenide (CIS), Copper Indium Gallium Selenide (CIGS), Cadmium Telluride (CdTe), thin film materials, or nanostructured materials.

65. (canceled)

66. (canceled)

67. (canceled)

68. (canceled)

69. The method of claim 63 wherein the first screen is a mesh stainless steel screen with a first predetermined grid pattern.

70. (canceled)

71. The method of claim 63 wherein the printing a first metallic paste through the first screen to form a first grid pattern and the printing a second metallic paste through the second screen to form a second grid pattern are carried at the temperature range 20 to 23° C. for forming fine grid lines.

72. (canceled)

73. (canceled)

74. (canceled)

75. (canceled)

76. (canceled)

77. The method of claim 63, further comprising drying the printed first metallic paste and/or the second metallic paste and/or the third metallic paste for about 2 to 3 minutes using an infrared dryer at a temperature of 120 to 130° C. before firing.

78. The method of claim 63 wherein the firing both the first surface and the second surface to cure the first grid pattern and the second grid pattern respectively further comprising:
applying infrared heat only towards the second metallic paste on the back surface at a peak temperature between 800 to 900° C. for 2 to 3 minutes;
applying infrared heat only towards the first metallic paste on the front surface at a peak temperature between 600 to 680° C. for 2 to 3 minutes.

79. (canceled)

80. (canceled)

81. (canceled)

82. (canceled)

83. (canceled)

84. (canceled)

85. (canceled)

86. (canceled)

87. (canceled)

88. (canceled)

89. (canceled)

90. (canceled)

91. (canceled)

92. (canceled)

93. (canceled)

94. (canceled)

95. (canceled)

96. (canceled)

97. (canceled)

98. (canceled)

99. (canceled)

100. (canceled)

101. (canceled)

102. (canceled)

103. (canceled)

104. (canceled)

105. (canceled)

106. (canceled)

107. (canceled)

108. (canceled)

109. (canceled)

110. (canceled)

111. (canceled)

112. (canceled)

113. (canceled)

114. (canceled)

115. (canceled)

116. (canceled)

117. (canceled)

118. (canceled)

119. (canceled)

120. (canceled)
